(19) United States
(12) Patent Application Publication
(10) Pub. No.: US 2019/0273054 A1
(43) Pub. Date: Sep. 5, 2019

(54) SUBSTRATE STRUCTURE AND METHOD FOR FABRICATING THE SAME

(71) Applicant: Siliconware Precision Industries Co., Ltd., Taichung City (TW)

(72) Inventors: Yi-Hsin Chen, Taichung City (TW); Chia-Hsin Wu, Taichung City (TW); Po-Yi Wu, Taichung City (TW)

(21) Appl. No.: 16/295,727

(22) Filed: Mar. 7, 2019

(30) Foreign Application Priority Data
Mar. 5, 2018 (TW) 107107234

(51) Int. Cl. H01L 23/00; H01L 23/498; H01L 21/48

(52) U.S. Cl. CPC H01L 24/02; H01L 24/13; H01L 23/49816; H01L 23/49866; H01L 2224/13024; H01L 2224/0239; H01L 2224/0231; H01L 2224/02331; H01L 21/4846

(57) ABSTRACT

A substrate structure and a method for fabricating the same are provided. A barrier layer is formed on an entire top surface of a wiring layer of a substrate body to isolate the wiring layer from moisture and prevent the wiring layer from being oxidized. Therefore, the wiring layer is securely bonded to an insulation layer, thereby preventing the delamination or peeling problem from occurring.

### CROSS REFERENCE TO RELATED APPLICATION

This application claims priority to Taiwanese Application No. 107107234, filed on Mar. 5, 2018, the entire contents of this application is incorporated herein by reference.

### BACKGROUND

### 1. Technical Field

The present disclosure relates to substrate structures, and, more particularly, to a substrate structure capable of improving reliability and a method for fabricating the same.

### 2. Description of the Prior Art

For a substrate structure, such as a chip or a package substrate, of a general electronic package, solder bumps are formed on conductive contacts and become solder balls during a reflow process, for an external device to be electrically connected thereto.

FIGS. 1A to 1D are schematic cross-sectional diagrams illustrating a method for fabricating a substrate structure 1 according to the prior art. As shown in FIG. 1A, a first passivation layer 11 and a second passivation layer 12 are sequentially formed on a semiconductor substrate 10 having at least one conductive contact 100, and a wiring layer 13 is then formed on the second passivation layer 12 and electrically connected to the conductive contact 100. Then, as shown in FIG. 1B, a solder mask layer 14 is formed on the wiring layer 13 and the second passivation layer 12, the solder mask layer 14 having an opening 140 that exposes at least one portion of a surface of the wiring layer 13. Then, as shown in FIG. 1C, an under bump metallurgy (UBM) 15 is formed on the wiring layer 13 in the opening 140. Then, as shown in FIG. 1D, a solder bump 16 is formed on the UBM 15 and electrically connected to the wiring layer 13, for an electronic device, such as a semiconductor component, a packaging substrate and circuit board, to be bonded thereto.

However, since the substrate structure 1 according to the prior art demands an increasing number of the conductive contact 100 and the wiring layer 13 is required to have an increased layout density, a contact surface between homogeneous protection layers (the first passivation layer 11 and the second passivation layer 12) is decreased, while a contact surface between the second passivation layer 12 and the heterogeneous wiring layer 13 (e.g., a copper layer) is increased. Therefore, the wiring layer 13 is likely to be delaminated from the second passivation layer 12. Specifically, the moisture in the air or the out gassing of the material itself contributes to generation of copper oxides, which results in the delamination problem. Thus, the wiring layer 13 is poorly bonded to and is likely to be peeled from the second passivation layer 12, which adversely affects the package reliability.

Therefore, how to solve the above problems of the prior art is becoming an urgent issue in the art.

### SUMMARY

In view of the problems of the prior art, the present disclosure provides a substrate structure, comprising: a substrate body having at least one conductive contact; an insulation layer formed on the substrate body, with the conductive contact exposed from the insulation layer; a wiring layer formed on the insulation layer and electrically connected to the conductive contact; and a barrier layer formed on an entire top surface of the wiring layer and made of nickel, titanium, vanadium, tungsten or tantalum, for example, nickel (Ni), titanium (Ti), nickel vanadium (NiV), titanium tungsten (TiW) as well as tantalum nitride (TaN), and preferably, nickel.

The present disclosure also provides a method for fabricating a substrate structure, comprising: providing a substrate body having at least one conductive contact, and forming an insulation layer on the substrate body, with the conductive contact exposed from the insulation layer; forming on the insulation layer a wiring layer electrically connected to the conductive contact; and forming a barrier layer covering an entire top surface of the wiring layer, wherein the barrier layer is made of nickel, titanium, vanadium, tungsten or tantalum, for example, nickel (Ni), titanium (Ti), nickel vanadium (NiV), titanium tungsten (TiW) as well as tantalum nitride (TaN), and preferably, nickel.

In an embodiment of the substrate structure and the method for fabricating the same, the barrier layer is a nickel layer.

In an embodiment of the substrate structure and the method for fabricating the same, an insulation protection layer is further formed on the barrier layer and the insulation layer.

In an embodiment of the substrate structure and the method for fabricating the same, a plurality of conductive elements are further disposed on the barrier layer.

Based on the above, in the substrate structure and the method for fabricating the same according to the present disclosure, the barrier layer covers the entire top surface of the wiring layer to isolate the wiring layer from the moisture in the air and the out gassing of the material itself, thereby preventing the generation of an oxide layer between the wiring layer and the insulation layer bonded to the wiring layer. Therefore, the wiring layer can be prevented from being delaminated or peeled from the insulation layer.

### BRIEF DESCRIPTION OF THE DRAWINGS

FIGS. 1A to 1D are schematic cross-sectional diagrams illustrating a method for fabricating a substrate structure according to the prior art; and

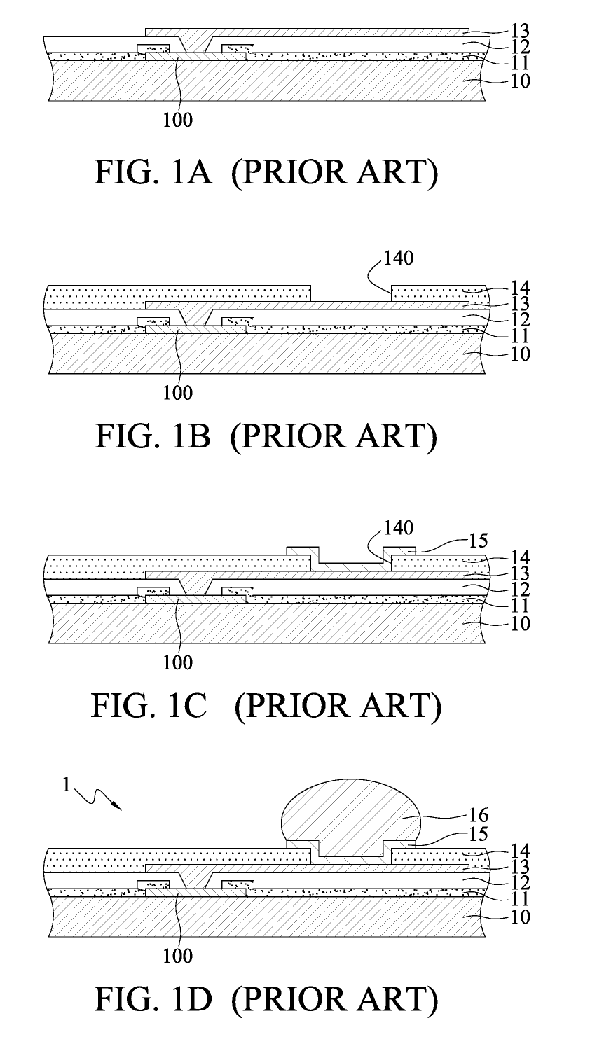

FIGS. 2A to 2D are schematic cross-sectional diagrams illustrating a method for fabricating a substrate structure according to the present disclosure.

### DETAILED DESCRIPTION OF THE EMBODIMENTS

The following illustrative embodiments are provided to illustrate the disclosure of the present disclosure, these and other advantages and effects can be apparently understood by those skilled in the art after reading the disclosure of this specification.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as falling within the scope covered by the technical contents disclosed herein. Meanwhile, terms such as “on”, “first”, “second”, “one”, “a”, “an” and the like are for illustrative purposes only, and are not meant to limit the scope implementable by the present disclosure. Any changes or adjustments made relative to their relationships, without modifying the substantial technical contents, are also to be construed as being within the scope implementable by the present disclosure.

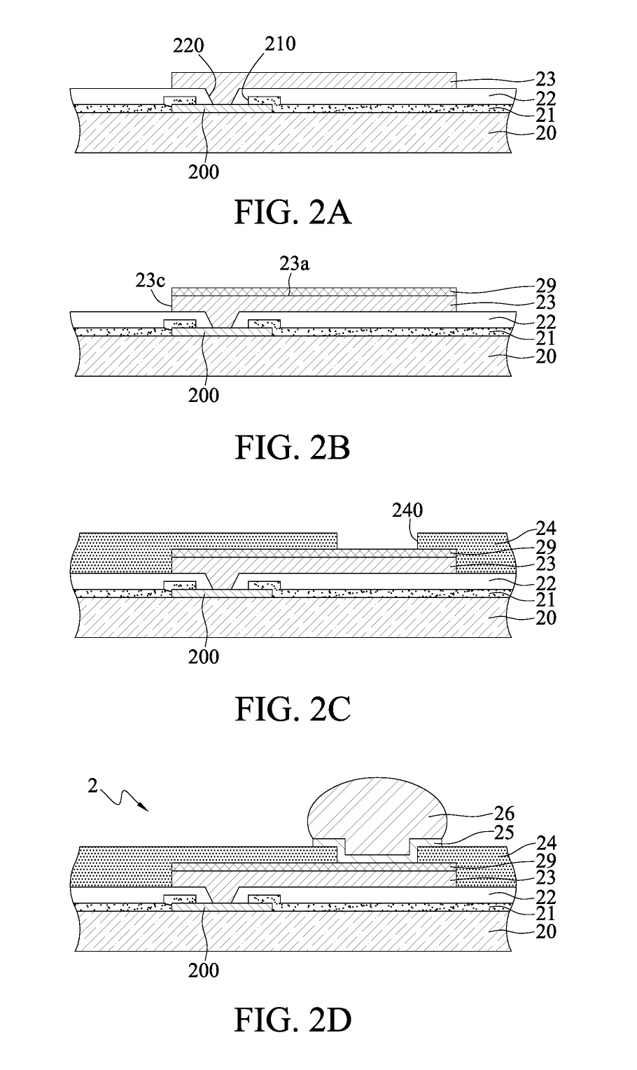

FIGS. 2A to 2D are schematic cross-sectional diagrams illustrating a method for fabricating a substrate structure 2 according to the present disclosure.

As shown in FIG. 2A, a first insulation layer 21 and a second insulation layer 22 are sequentially formed on a substrate body 20 having at least one conductive contact 200, and a wiring layer 23 is then formed on the second insulation layer 22.

The substrate body 20 is an insulation plate, a metal plate, or a semiconductor plate, such as a wafer, a chip, a silicon material and glass. For example, the substrate body 20 is a through silicon interposer (TSI) or a glass substrate, and has through-silicon vias (TSVs) and a distribution layer, such as a fan-out redistribution layer (RDL), with the ends of the TSVs and the conductive pads of the distribution layer serving as the conductive contact 200; or the substrate body 20 is a packaging substrate, and includes a circuit structure having a coreless layer or a circuit structure having a core layer. The circuit structure includes a distribution layer, such as an RDL, and has conductive pads that can serve as the conductive contact 200.

The first insulation layer 21 is formed with at least one first opening 210 corresponding to exposing at least one portion of a surface of the conductive contact 200. Also, materials for the first insulation layer 21 can be an oxide (e.g., SiO2) layer or a nitride (e.g., SixNy) layer serving as a passivation layer.

The second insulation layer 22 is formed on the first insulation layer 21, and is formed with at least one second opening 220 corresponding to the first opening 210 and exposing at least one portion of a surface of the conductive contact 200. The second insulation layer 22 is made of a dielectric material, such as Polyimide (PI), Prepreg (PP), Benezocy-clobutene (BCB) and Polybenzoxazole (PBO).

The wiring layer 23 extends into the second opening 220 and is in contact with and electrically connected to the conductive contact 200. In an embodiment of the present disclosure, the wiring layer 23 is fabricated in an RDL process and is made of a conductive material, such as copper (Cu).

As shown in FIG. 2B, a barrier layer 29 is formed on the wiring layer 23 and is in contact with and covers an entire top surface 23a of the wiring layer 23, without being in contact with the second insulation layer 22 and a lateral surface 23c of the wiring layer 23.

In an embodiment of the present disclosure, the barrier layer 29 is made of metal, such as nickel (Ni), titanium (Ti), vanadium (V), tungsten (W), or tantalum (Ta), for example, nickel (Ni), titanium (Ti), nickel vanadium (NiV), titanium tungsten (TiW), tantalum nitride (TaN) as well as other suitable materials, and most preferably, nickel. The barrier layer 29 is formed on the wiring layer 23 directly when the wiring layer 23 is fabricated.

As shown in FIG. 2C, an insulation protection layer 24, such as a solder mask layer, is formed on the barrier layer 29 and the second insulation layer 22, and is formed with an opening 240 exposing at least one portion of a surface of the barrier layer 24.

As shown in FIG. 2D, an under bump metallurgy (UBM) 25 is formed on the barrier layer 24 in the opening 240, and a conductive element 26 is disposed on the UBM 25 and electrically connected to the wiring layer 23, for an electronic device, such as a semiconductor component, a packaging substrate and a circuit board, to be bonded thereto.

In an embodiment of the present disclosure, the conductive element 26 is a solder ball, a metal bump (in shape of ball or pillar), or the like.

Based on the substrate structure according to the present disclosure, the barrier layer 29 is formed on the wiring layer 23 to isolate from the moisture in the air and the out gassing of the material itself, prevent the generation of an oxide layer between the wiring layer 23 and the second insulation layer 22 (or the insulation protection layer 24), and ensure that the wiring layer 23 is securely bonded to the second insulation layer 22 (or the insulation protection layer 24). Therefore, the wiring layer 23 is not peeled from the second insulation layer 22 (or the insulation protection layer 24). Compared with the prior art, the substrate structure according to the present disclosure does not suffer from the delamination problem occurring between the wiring layer 23 and the second insulation layer 22 (or the insulation protection layer 24. At the same time, the barrier layer 29 used is made of a general material, and will not additionally increase the fabrication cost of the substrate structure.

The present disclosure also provides a substrate structure 2, which comprises a substrate body 20 having at least one conductive contact 200, a first insulation layer 21 and a second insulation layer 22 formed on the substrate body 20, a wiring layer 23 formed on the second insulation layer 22 and electrically connected to the conductive contact 200, and a barrier layer 29 formed on the wiring layer 23.

In an embodiment of the present disclosure, the barrier layer 29 is made of metal.

In an embodiment of the present disclosure, the barrier layer 29 is a nickel layer.

In an embodiment of the present disclosure, the substrate structure 2 further comprises an insulation protection layer 24 formed on the barrier layer 29 and the second insulation layer 22.

In an embodiment of the present disclosure, the substrate structure 2 further comprises a plurality of conductive elements 26 disposed on the barrier layer 29.

Given the foregoing, based on a substrate structure and a method for fabricating the same according to the present disclosure, a barrier layer is formed on a wiring layer to isolate the wiring layer from the moisture in the air and the out gassing of the material itself, prevent the generation of an oxide layer between the wiring layer and an insulation layer made of a different material from the wiring layer, and ensure that the wiring layer is securely bonded to the insulation layer. Therefore, the delamination or peeling problem of the prior art is solved.

The foregoing descriptions of the detailed embodiments are only illustrated to disclose the features and functions of the present disclosure and should not be construed as to limit the scope of the present disclosure. Any of the above described embodiments can be modified by those skilled in the art without departing from the spirit and scope of the present disclosure. Therefore, the protection sought herein is as set forth in the appended claims.

What is claimed is:

1. A substrate structure, comprising:
a substrate body having at least one conductive contact;
an insulation layer formed on the substrate body, with the conductive contact exposed from the insulation layer;
a wiring layer formed on the insulation layer and electrically connected to the conductive contact; and
a barrier layer formed on an entire top surface of the wiring layer and made of nickel, titanium, vanadium, tungsten or tantalum.

2. The substrate structure of claim 1, wherein the barrier layer is a nickel layer.

3. The substrate structure of claim 1, further comprising an insulation protection layer formed on the barrier layer and the insulation layer.

4. The substrate structure of claim 1, further comprising a plurality of conductive elements disposed on the barrier layer.

5. A method for fabricating a substrate structure, comprising:
providing a substrate body having at least one conductive contact;
forming an insulation layer on the substrate body, with the conductive contact exposed from the insulation layer;
forming on the insulation layer a wiring layer electrically connected to the conductive contact; and
forming a barrier layer covering an entire top surface of the wiring layer, wherein the barrier layer is made of nickel, titanium, vanadium, tungsten or tantalum.

6. The method of claim 5, wherein the barrier layer is a nickel layer.

7. The method of claim 5, further comprising forming an insulation protection layer on the barrier layer and the insulation layer.

8. The method of claim 5, further comprising forming a plurality of conductive elements on the barrier layer.
